(19) United States
(12) Patent Application Publication
(10) Pub. No.: US 2005/0035788 A1
(43) Pub. Date: Feb. 17, 2005

(54) Clamped comparator

(76) Inventors: Don C. Devendorf, Carlsbad, CA (US); Erick M. Hirata, Torrance, CA (US); Robert M. Horhota, Ontario, CA (US); Christopher B. Langit, Gardena, CA (US); Lloyd F. Linder, Agoura Hills, CA (US); Phung N. Phan, Simi Valley, CA (US)

Correspondence Address: David T. Yang, Esq.;Morrison & Foerster LLP, Suite 3500, 555 West Fifth Street, Los Angeles, CA, 90013-1024, US

(21) Appl. No.: 10/740,334

(22) Filed: Dec. 18, 2003

Related U.S. Application Data
(60) Provisional application No. 60/495,767, filed on Aug. 14, 2003.

(51) Int. Cl. H03D 1/00

(52) U.S. Cl. 327/65

(57) ABSTRACT

A clamped comparator. The novel comparator includes a first circuit for comparing first and second input signals and generating a digital output, and a second circuit for receiving a control signal and in accordance therewith decoupling the input signals from the output. The second circuit includes one or more switching circuits adapted to clamp the signal path between the input signals and the output when the circuit is operating in a ‘mute’ mode. In an illustrative embodiment, the comparator also includes a pre-amplifier with an amplifier stage, and the switching circuit is adapted to turn off the amplifier stage and/or steer the outputs of the amplifier stage out of the signal path, when the circuit is in the ‘mute’ mode.

### CROSS-REFERENCE TO RELATED APPLICATIONS

This application claims the benefit of U.S. Provisional Application No. 60/495,767, filed Aug. 14, 2003, the disclosure of which is hereby incorporated by reference.

### BACKGROUND OF THE INVENTION

1. Field of the Invention

The present invention relates to electronics. More specifically, the present invention relates to analog to digital converters.

2. Description of the Related Art

Analog to digital converters are widely used for converting analog signals to corresponding digital signals for many electronic circuits. For example, a high resolution, high speed analog to digital converter (ADC) may find application in broadband communications, video circuits, radar, and electronic warfare applications. In the field of analog to digital conversion, there continue to be many driving goals, such as speed, increased number of bits (relating to dynamic range and spur-free operation), power consumption, and size. Two of the most critical specifications remain speed and dynamic range.

The fastest ADC architecture is called “flash” conversion. A flash ADC produces an N-bit digital output in one step using a comparator bank comprised of 2^{N}−1 parallel comparators. This architecture, however, is limited in dynamic range to about 8 bits, since the number of comparators grows rapidly as the number of bits N becomes larger. The next fastest converter technique is a subranging pipelined architecture.

Subranging ADCs typically use a low resolution flash quantizer during a first stage or “coarse pass” to convert an analog input signal into the most significant bits (MSB) of its digital value. A reconstruction circuit then subtracts an analog version of the MSB word from the input signal at a summing node to produce a residue or residual signal. The residue signal is similarly digitized by one or more additional stages or “fine passes” (through the same quantizer or additional low resolution quantizers) to produce the lower significant bits of the input signal. The digital words produced by each stage are then combined by digital error correcting circuitry to produce a digital output representing the original analog input signal.

There are several subranging architectures that exist in the literature and in practice. In the fastest architectures for subranging and pipelined ADCs, the input voltage: to each stage can couple through the quantizer's comparator bank, even though the comparators are latched, permitting signal feedthrough into that stage's summing node. This feedthrough adds distortion and spurious signal inputs to the following stages of the ADC, resulting in degradation of accuracy and settling time, and reducing the effective dynamic range of the ADC. For moderate dynamic range ADCs (10 bits or less), this feedthrough can usually be ignored; however, for larger dynamic range converters (12 bits or larger), slower converter architectures have been used instead to reduce the spurious contribution.

Hence, there is a need in the art for an improved analog to digital converter offering faster speed and larger dynamic range than prior art approaches.

### SUMMARY OF THE INVENTION

The need in the art is addressed by the clamped comparator of the present invention. The novel comparator includes a first circuit for comparing first and second input signals and generating a digital output, and a second circuit for receiving a control signal and in accordance therewith decoupling the input signals from the output. The second circuit includes one or more switching circuits adapted to clamp the signal path between the input signals and the output when the circuit is operating in a ‘mute’ mode. In an illustrative embodiment, the comparator also includes a pre-amplifier with an amplifier stage, and the switching circuit is adapted to turn off the amplifier stage and/or steer the outputs of the amplifier stage out of the signal path, when the circuit is in the ‘mute’ mode. The novel comparator is used in the quantizer of a subranging ADC to significantly reduce distortions due to signal feedthrough.

### BRIEF DESCRIPTION OF THE DRAWINGS

FIG. 1 is a simplified block diagram of a typical high speed subranging ADC of conventional design and construction.

FIG. 2 is a simplified block diagram of the conventional subranging ADC illustrating the parasitic capacitances in the circuit.

FIG. 3 is an equivalent circuit of the leakage path from Vᵢₙ to the output Vₒᵤₜ of the DAC into the summing node.

FIG. 4 is a simplified block diagram of an alternate configuration of a conventional subranging ADC.

FIG. 5 is a simplified block diagram of a subranging ADC designed in accordance with an illustrative embodiment of the teachings of the present invention.

FIG. 6 is a simplified block diagram of an illustrative embodiment of a quantizer designed in accordance with the teachings of the present invention.

FIG. 7 is a simplified schematic of an illustrative pre-amplifier implementation designed in accordance with an illustrative embodiment of the teachings of the present invention.

FIG. 8 is a simplified schematic of a pre-amplifier implementation designed in accordance with an alternative embodiment of the teachings of the present invention.

FIG. 9 is a simplified schematic of another pre-amplifier implementation designed in accordance with an alternative embodiment of the teachings of the present invention.

### DESCRIPTION OF THE INVENTION

Illustrative embodiments and exemplary applications will now be described with reference to the accompanying drawings to disclose the advantageous teachings of the present invention.

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

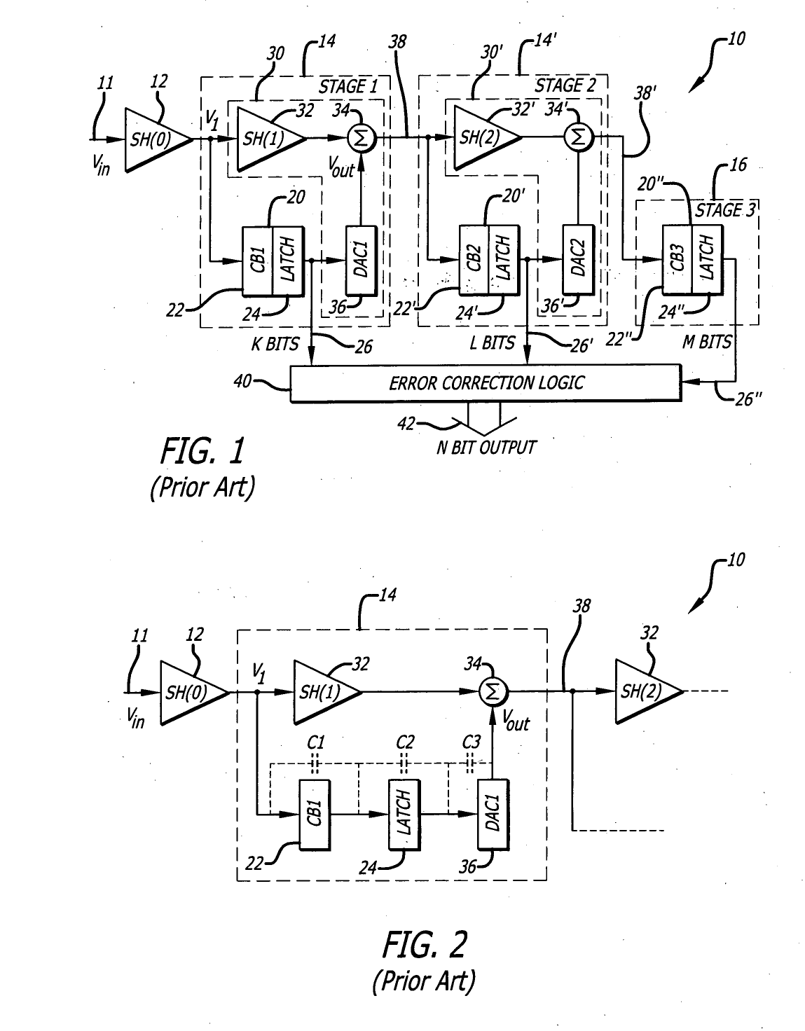

FIG. 1 is a simplified block diagram of a typical high speed subranging ADC 10 of conventional design and construction. In the example shown, the ADC 10 includes three stages 14, 14′, and 16. An analog input signal Vᵢₙ is applied to an input node 11 connected to a first sample and hold (S/H) circuit 12, which outputs a voltage V₁. The sampled voltage V₁ is then input to the first subranging stage 14, which includes a first quantizer 20 for digitizing the input signal to K bits, and a first reconstruction circuit 30 for subtracting an analog version of the K-bit digital output 26 of the quantizer 20 from the sampled input signal V₁ to generate a first residue signal 38.

The first residue signal 38 is similarly processed by the second stage 14′, which includes a second quantizer 20′ for digitizing the first residue 38 to L bits, and a second reconstruction circuit 30′ for subtracting an analog version of the L-bit digital output 26′ of the second quantizer 20′ from the first residue 38 to generate a second residue signal 38′. The second residue signal 38′ is then digitized by the third stage 16, which includes only a third quantizer 20″ for generating an M-bit digital output 26″.

Error correction logic 40 combines the K-bit output 26, L-bit output 26′, and the M-bit output 26″ to produce an N-bit digital output 42 representing the original analog input signal. A typical bit allocation is 5 bits (K) for the first stage 14, 5 bits (L) for the second stage 14′, and 6 bits (M) for the last stage 16. One bit from each of the second and third stages is used by the error-correction logic; therefore, this converter would have a dynamic range of 14 bits (N).

The quantizer 20 is typically a low resolution ADC such as a flash converter, which includes a comparator bank 22 and a latches and decoding circuit 24. The reconstruction circuit 30 includes a second S/H circuit 32 for sampling the output V₁ of the first S/H 12, a DAC 36 for generating an analog version of the output of the quantizer 20, and a summing node 34 for subtracting the output of the DAC 36 from the output of the second S/H 32 to generate the residue signal 38. The quantizer 20′ and reconstruction circuit 30′ of the second stage 14′ are similar to the quantizer 20 and reconstruction circuit 30 of the first stage 14, and have components labeled similar to the corresponding components of the first stage 14, followed by a prime (′).

The second S/H 32 allows the circuit 10 to operate at a higher speed. After the S/H 32 has captured the input voltage V₁ and the latches 24 have captured the output of the comparator banks 22, the first S/H 12 can then be switched to track mode to sample the next input, giving the first S/H 12 additional time to settle while the rest of the circuit continues to compute the digital value of the first input sample.

This architecture results in the highest throughput; however, it is deficient when operating at high speeds, such as with a 250 MHz video frequency input. One problem with this architecture is that when the second S/H 32 is in hold mode and the first S/H 12 switches to track, the input voltage Vᵢₙ is allowed to pass and can couple through the quantizer 20, even though the comparators 22 are latched, permitting signal feedthrough into the summing node 34. It should be pointed out that when the first S/H 12 is switched to track, it initially is slew rate limited and its output is highly nonlinear due to the dV/dt limit of the S/H 12. This highly distorted, nonlinear voltage is coupled through successive multi-order high pass parasitic capacitive coupling at each stage of circuitry.

FIG. 2 is a simplified block diagram of the conventional subranging ADC 10 illustrating the parasitic capacitances in the circuit. Only the first stage 14 of the ADC 10 is shown for simplicity. The spurious input voltage V₁ at the output of the first S/H 12 is input to the comparator bank 22 of the first quantizer 20, which has a parasitic capacitance C1 (shown in FIG. 2 with dotted lines). Even though the output of the comparator bank 22 is latched and should therefore be held constant, some signal is coupled through the latches 24 into the DAC 36 switches, due to a parasitic capacitance C2 of the latches 24. The signal is then coupled through to the output of the DAC 36, due to a parasitic capacitance C3 of the DAC 36, and into the summing node 34, adding a nonlinear error to the residue signal 38. This same coupling occurs for the second stage 14′ as well when the first summing node 34 unclamps. For low and moderate resolution ADCs (less than about 10 bits), the coupled feedthrough is unnoticeable because the error is smaller than the resolution of the ADC. For larger resolution ADCs, however, the error becomes significant. The coupled spurious feedthrough therefore reduces the effective dynamic range of the ADC.

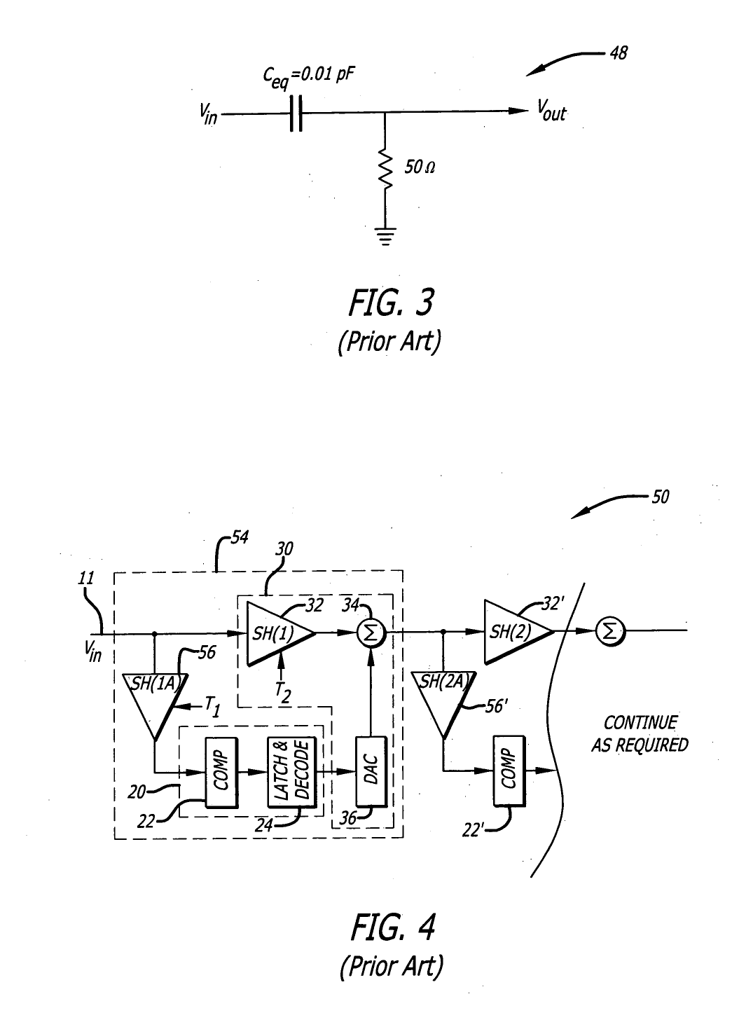

The following analysis shows how this nonlinear feedthrough of the input signal is coupled. For a K=5 bit stage there are 2^{K-1} or 31 comparators 22 and latches 24, each with some finite capacitance from input to output. The same situation exists for the DAC 36. A review of typical comparator 22, latch 24, and DAC 36 circuitry, along with other stray coupling paths, yields the following conservative set of values for C1, C2 and C3. Let C1=0.03 pF, C2=0.03 pF, and C3=0.03 pF. Since they are effectively in series, there is the equivalent of a C_{eq}=0.01 pF capacitor in series with a 50 Ω resistor (the summing node 34 impedance) as shown in FIG. 3. FIG. 3 is an equivalent circuit 48 of the leakage path from Vᵢₙ to the output Vₒᵤₜ of the DAC 36 into the summing node 34. While this analysis is a simplification of the complex coupling paths, it clearly demonstrates the problem.

$$For {V}_{in} = + / - 2 V at 250 MHz , {V}_{out} = 50 {V}_{in} / ( 50 + \frac{1}{2 π {fC}_{eq}} ) = 3 mV .$$

Assuming a +/−2 V input and assuming 3 mV of spurious feedthrough=½ LSB (least significant bit), this would limit the ADC's performance to 4 V divided by 6 mV, or 1 part in 666 which is almost a 10 bit converter. This level of spurious coupling of the slew limited errors thus limits the ADC spur free dynamic range (SFDR) to about 10 bits for most applications.

FIG. 4 is a simplified block diagram of an alternate configuration of a prior art subranging ADC 50, as described in U.S. Pat. No. 6,396,429, entitled “FRONT-END SAMPLING FOR ANALOG-TO-DIGITAL CONVERSION.” Only the first stage 54 of the multi-stage subranging ADC 50 is shown for simplicity. The circuit 50 is identical to that of FIG. 1, except for the removal of the input S/H 12, and the addition of a S/H 56 to each stage of the circuit, preceding the quantizer 20. Thus, the input signal Vᵢₙ is applied to the input terminal 11, which is connected to the reconstruction S/H 32 and the quantizer S/H 56 of the first stage 54. The reconstruction S/H 32 samples at a time T₁ and the quantizer S/H 56 samples at a time T₂. The output of the quantizer S/H 56 is input to the quantizer 20.

This architecture eliminates the feedthrough problem of FIG. 1; however, it has two other problems. The most serious problem is that by eliminating the input S/H 12 (reference FIG. 1), the aperture uncertainty Tₐ=T₁−T₂ between the reconstruction S/H 32 and the quantizer S/H 56 becomes significant. Also, any signal skews in the analog path between the reconstruction S/H 32 and the quantizer S/H 56 becomes an encoding error. In order for the error correction scheme to work, the reconstruction S/H 32 and the quantizer S/H 56 must be strobed so that the difference between the output voltage of the reconstruction S/H 32 and the comparators 22 decision is less than V_{in peak}/2^{A} where A=5. This assumes no additional error in the DAC 36 itself. This is a requirement for the error correction circuit 40 to function properly and correct for the error made by the first stage 54 downstream. The major source of this error is aperture uncertainty Tₐ. The maximum rate of change seen by the S/H circuits is dVₘₐₓ/dt=2πfVᵢₙ. Since the maximum error allowed in this architecture is Vᵢₙ/2^{A}, 2πfVᵢₙ(Tₐ) is equal to or less than Vᵢₙ/2^{A} or, Tₐ is equal to or less than 1/(2πf2^{A}), which, at a frequency of 250 MHz, equals 20 ps. This is very difficult to achieve; therefore, this approach will not work as well without an input S/H 12. If an input S/H 12 is added to the ADC 50 between the input terminal 11 and the first stage 54 (as in FIG. 1), this would eliminate the need for accurate timing between the reconstruction S/H 32, the quantizer S/H 56, and the latch command since the input voltage is held constant. However, if the quantizer S/H 56 is left in the circuit path to the comparators 22, two problems exist. First, the conversion rate of the ADC 50 is slowed due to the settling times of the quantizer S/H 56 in the first stage 54 and the quantizer S/H 56′ in the second stage. Secondly, they perform a sample and hold function that is not really required, taking up valuable real estate and dissipating power unnecessarily.

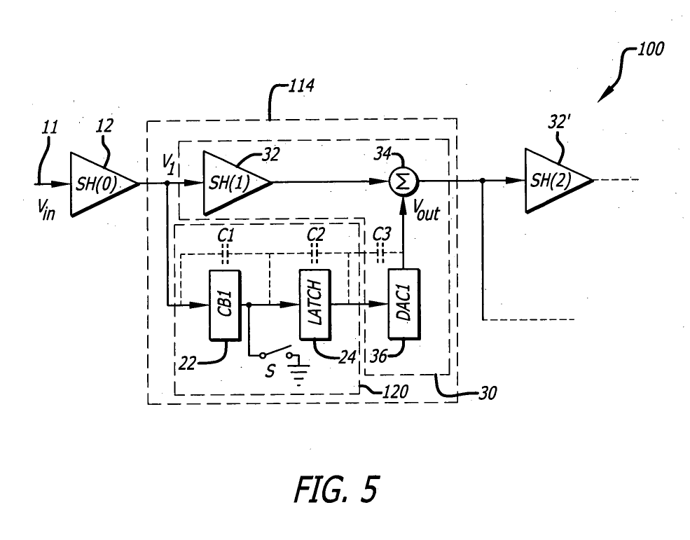

FIG. 5 is a simplified block diagram of a subranging ADC 100 designed in accordance with an illustrative embodiment of the teachings of the present invention. Conceptually, the invention adds a switching mechanism (to the ADC of FIG. 1) adapted to receive a control signal and in accordance therewith, decouple the input signal Vin from the output Vₒᵤₜ of the DAC 36. This is accomplished by adding a switch S somewhere in the signal path to clamp or ‘mute’ the signal before it can feed through the latches 24 and DAC 36 to the summing node 34. The switch S is controlled to mute the signal after the comparators 22 have been latched, to reduce signal feedthrough from the spurious input voltages at the output of the first S/H 12.

Only the first stage 114 of the multi-stage subranging ADC 100 is shown in FIG. 5 for simplicity; however, the ADC 100 may include any number of subranging stages without departing from the scope of the present teachings. Furthermore, a single-ended architecture is shown in FIG. 5 for simplicity. The principles discussed, however, are applicable to single-ended or differential implementations.

The ADC 100 is identical to that of FIG. 1, except for the addition of the switch S in the leakage path to decouple the output V₁ of the input S/H 12 from the output Vₒᵤₜ of the DAC 36. Additional switches may be added in a similar manner to the other subranging stages of the ADC 100. The parasitic capacitances C1, C2, and C3 of the comparator bank 22, latches 24, and DAC 36, respectively, are shown in dotted lines. In the illustrative embodiment of FIG. 5, the switch S is placed within the quantizer 120 between the comparators 22 and the latches 24, to, ground out any signal that passes through the comparators 22, so that nothing couples through to C2 and C3. The switch S may be placed anywhere in the leakage path without departing from the scope of the present teachings.

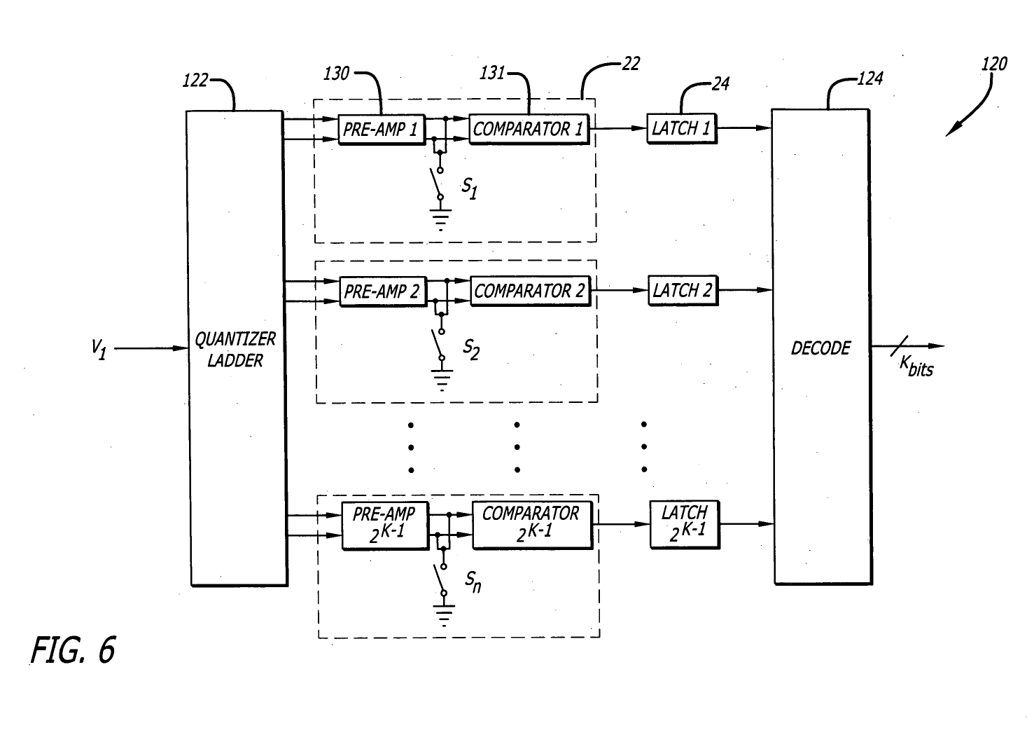

FIG. 6 is a simplified block diagram of an illustrative embodiment of a quantizer 120 designed in accordance with the teachings of the present invention. The quantizer 120 includes a comparator bank of 2^{K}−1 parallel comparator circuits 22. The threshold inputs to the comparator circuits 22 are supplied by a quantizer ladder 122. The output of each comparator circuit 22 is captured and stored by a latch 24 and decoded by a decoding logic circuit 124 to produce a K-bit digital output.

Each comparator circuit 22 includes a pre-amplifier (pre-amp) or input stage 130 followed by a comparator stage 131. The pre-amplifier 130 receives and amplifies a differential signal from the quantizer ladder 122. The comparator stage 131 receives and compares the two signals from the pre-amplifier 130 and outputs a digital signal indicating whether the difference between the two signals is positive or negative. This digital output is then captured by the latch 24.

In accordance with the teachings of the present invention, the quantizer 120 also includes a plurality of switches Sₙ, for n=1 to 2^{K}−1, one switch Sn added to each comparator circuit 22 to decouple V₁ from the input to the latches 24. For example, the switch Sₙ may be implemented before, within, or after the pre-amplifier 130, or before, within, or after the comparator 131. The switch Sₙ is adapted to clamp the signal path between the input and output of the comparator circuit 22 to AC ground. More than one switch can be added to each comparator circuit 22 to clamp the signal path at several different points, for improved isolation.

In the illustrative embodiment of FIG. 6, a switch Sₙ is added within each comparator circuit 22 to clamp the output of the pre-amplifiers 130. By adding a switch Sₙ in the pre-amplifier 130, it is possible to reduce the voltage swings seen by the comparators 131 by at least 40 dB. This reduction then carries through to the feedthrough voltage Vₒᵤₜ as seen in the summing node 34, since it is in series with the leakage path described previously. Where before, the noise seen at the summing node 34 was 3 mV, a 40 dB reduction in amplitude reduces this to 0.03 mV, which is greater than a 6 bit improvement, consistent with a 16-bit converter.

It should be noted that adding a switch is, in general, the addition of two to four transistors, depending on the switch implementation chosen. The fastest implementation adds no delay to the signal path and therefore does not detract from the maximum sample rate of the ADC. In an illustrative embodiment, the signal feedthrough is muted by clamping the pre-amplifiers 130 to the comparators 131 without adding unnecessary delays to the maximum sample rate of the ADC 100. Several circuit approaches might be employed to accomplish this end. Three implementations will now be described.

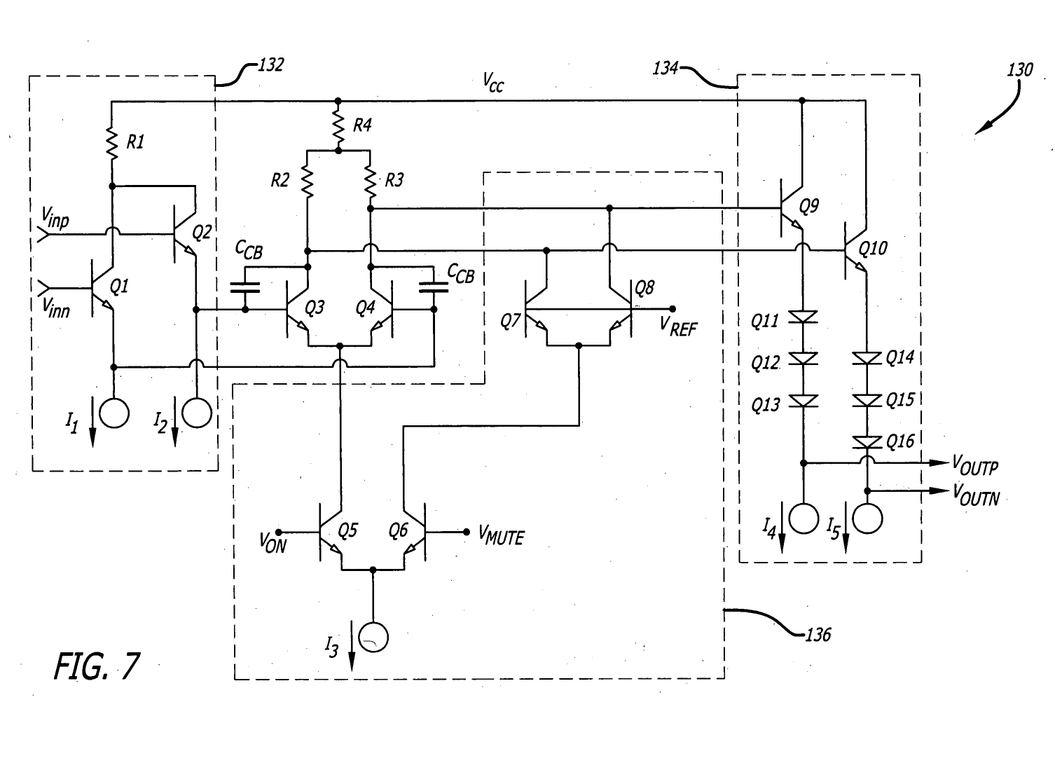

FIG. 7 is a simplified schematic of a pre-amplifier 130 implementation designed in accordance with an illustrative embodiment of the teachings of the present invention. The pre-amplifier 130 includes an amplifier stage comprised of an input differential pair Q3 and Q4, each having a parasitic collector-base capacitance C_{CB}. The bases of Q3 and Q4 are adapted to receive a differential signal from an input buffer circuit 132, and the collectors are coupled to an output circuit 134. The collectors of Q3 and Q4 are also connected to resistors R2 and R3, respectively, which are both connected to a voltage supply V_{CC} by a resistor R4.

In an illustrative embodiment, the input circuit 132 includes a pair of emitter followers Q1 and Q2, having bases coupled to a differential input signal Vᵢₙₙ and Vᵢₙₚ, respectively, collectors connected in common to V_{CC} through a resistor R1, and emitters connected to current sources 11 and 12, respectively. The collector of Q1 is coupled to the base of Q4, and the collector of Q2 is coupled to the base of Q3. The output circuit 134 includes a pair of emitter followers Q9 and Q10, having bases coupled to the collectors of Q4 and Q3, respectively, collectors connected in common to V_{CC}, and emitters coupled to current sources 14 and 15, respectively. A series of diodes Q11, Q12, and Q13 may be connected between the emitter of Q9 and the current source I4, and a series of diodes Q14, Q15, and Q16 may be connected between the emitter of Q10 and the current source I5 to ensure a desired common mode voltage. In FIG. 7, the differential output Vₒᵤₜₚ and Vₒᵤₜₙ is taken at the nodes between Q13 and 14, and between Q16 and 15, respectively. It should be pointed out that the common mode voltage of Vₒᵤₜₚ and Vₒᵤₜₙ could be changed by taking their outputs from the emitters of Q9, Q10 or the cathodes of Q11, Q14 or the cathodes of Q12, Q15.

In accordance with the teachings of the present invention, a switching circuit 136 is added to the pre-amplifier 130 to decouple the input voltages Vᵢₙₚ and Vᵢₙₙ from the output circuit 134. The switching circuit 136 includes a pair of switching transistors Q5 and Q6, having bases connected to control signals V_{ON} and its complement V_{MUTE}, respectively, and emitters connected in common to a current source I3. The collector of Q5 is coupled to the common emitters of Q3 and Q4. The collector of Q6 is coupled to the common emitters of two transistors Q7 and Q8, which, when on, split the current from Q6 between the resistors R2 and R3. The bases of Q7 and Q8 are connected in common to a reference voltage V_{REF}, and the collectors are connected to the bases of Q10 and Q9, respectively.

In operation, the input differential pair Q3 and Q4 is switched on and off by the gating signals V_{ON} and V_{MUTE}. When the circuit 130 is in ‘active’ mode, V_{ON} is on (and V_{MUTE} is therefore off), Q5, Q3 and Q4 are on, and Q6, Q7 and Q8 are off. When Q5 is on, Q3 and Q4 receive input signals from the quantizer ladder 122, so Q3 and Q4 act as a differential pair in response to the input signal, and the circuit 130 acts as a normal pre-amplifier.

After the comparator 131 following the pre-amplifier 130 is latched, V_{MUTE} is switched on. When V_{MUTE} is on (and V_{ON} is therefore off), Q5, Q3 and Q4 are off and Q6, Q7 and Q8 are on. Once Q5 is off, Q3 and Q4 cease to be amplifiers. Transistors Q7 and Q8 are cascodes and when Q6 is on, the current splits between Q7 and Q8. This allows the comparator input to be at the common mode voltage of the preamp. Essentially, when the circuit 130 is in ‘mute’ mode, Q7 and Q8 keep the output of the pre-amplifier 130 balanced, and the feedthrough is reduced by approximately 40 dB since Q3 and Q4 are off. The attenuated feedthrough is coupled only through the base collector capacitances of Q3 and Q4. V_{ON} is switched back on when the comparator 22 is ready to receive the next input sample.

For the embodiment of FIG. 7, note that a second stage of muting could be added at the load resistors to lower that impedance further, or a set of additional transistors could be added at Q9 and Q10 to act as a differential pair and shut off Q9 an Q10 in mute mode. There are a number of configurations that are possible and the tradeoffs become size, power, settling time, and isolation.

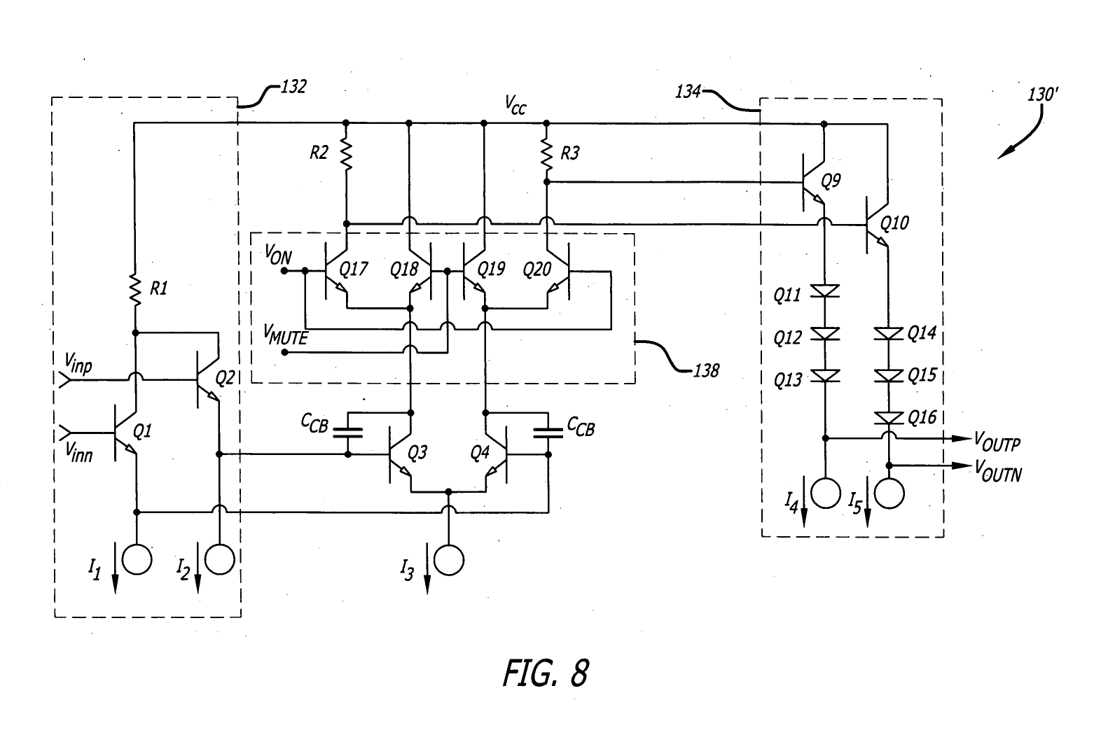

FIG. 8 is a simplified schematic of a pre-amplifier 130′ implementation designed in accordance with an alternative embodiment of the teachings of the present invention. As in FIG. 7, the pre-amplifier 130′ includes a differential pair Q3 and Q4, an input circuit 132, and an output circuit 134. The emitters of Q3 and Q4 are connected in common to the current source I3. Q3 and Q4 are therefore always ‘on’ in this implementation. A switching circuit 138 is added between the collectors of Q3 and Q4 and the output circuit 132. The switching circuit 138 includes a first switching pair Q17 and Q18 having emitters connected in common to the collector of Q3, and a second switching pair Q19 and Q20 having emitters connected in common to the collector of Q4. The bases of Q17 and Q20 are connected to V_{ON} and the collectors are connected V_{CC} through resistors R2 and R3, respectively. The collectors of Q17 and Q20 are also coupled to the bases of Q10 and Q9 of the output circuit 134. The bases of Q18 and Q19 are connected to V_{MUTE} and the collectors are connected directly to V_{CC}.

The embodiment of FIG. 8 differs from that of FIG. 7 in that the input differential pair Q3 and Q4 is left ‘on’, but their collector currents are steered out of the signal path when V_{MUTE} is on. When V_{ON} is on, the differential signal path is through Q17 and Q20, and the input signals are coupled as normal to the output circuit 134. Transistors Q18 and Q19 are off. When V_{MUTE} is on, Q17 and Q20 are switched off, and the signal currents are switched to AC ground through Q18 and Q19, which are now on. So in this configuration, the feedthrough is capacitively coupled to a low impedance that is not in the signal path. As a result, this implementation has improved isolation over the implementation of FIG. 7.

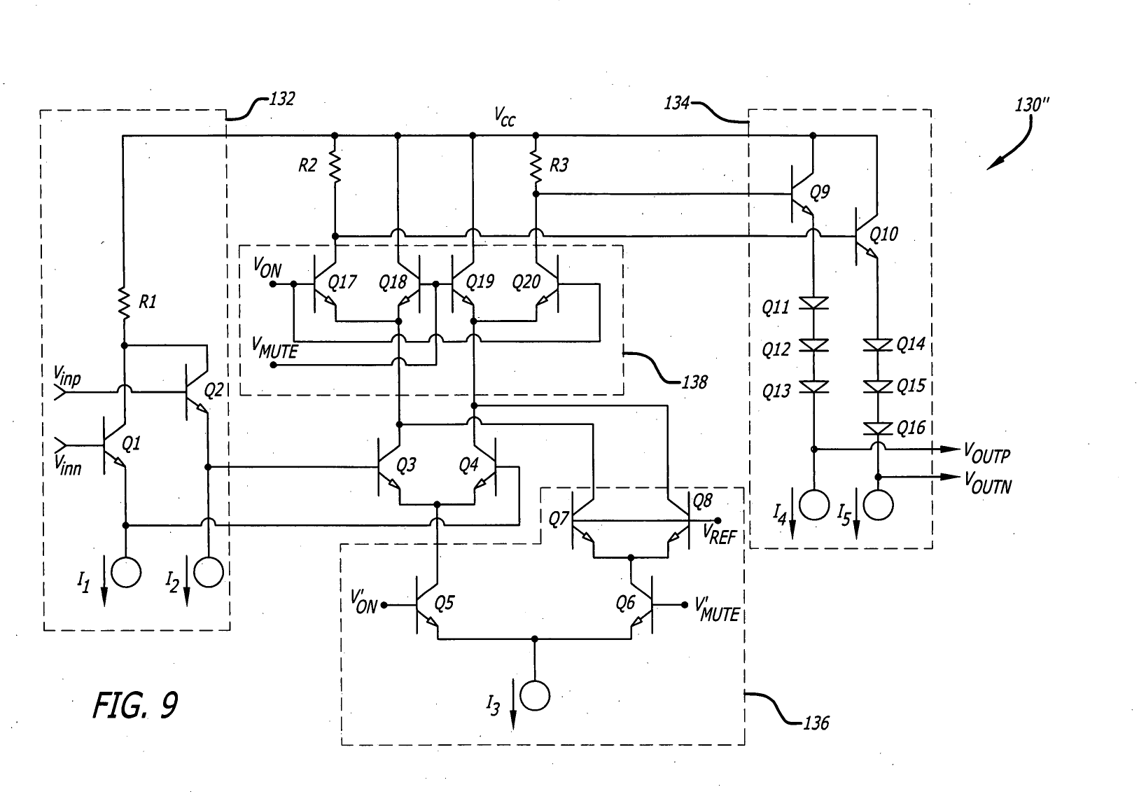

FIG. 9 is a simplified schematic of pre-amplifier 130″ implementation designed in accordance with another alternative embodiment of the teachings of the present invention. This implementation is essentially a combination of the embodiments of FIGS. 7 and 8. The pre-amplifier 130″ includes a differential pair Q3 and Q4, an input; circuit 132, and an output circuit 134. A first switching circuit 136, comprised of a switching pair Q5 and Q6, a current source I3, and transistors Q7 and Q8, is adapted to turn Q3 and Q4 on and off, as in FIG. 7. A second switching circuit 138, comprised of switching pairs Q17, Q18 and Q19, Q20, is adapted to steer the collector currents of Q3 and Q4 in and out of the signal path, as in FIG. 8. The second switching circuit 138 is controlled by V_{ON} and its complement V_{MUTE}, as described above. The first switching circuit 138 is controlled by V′_{ON} and its complement V′_{MUTE}, which are level shifted versions of V_{ON} and V_{MUTE}, respectively.

In operation, the current 13 is routed through Q3 and Q4 when Q5 is switched on. When Q5 is switched off, Q3 and Q4 no longer act as amplifiers since I3 is now routed through Q6 to Q7 and Q8, which allow Q18 and Q19 to reduce the feedthrough signal further.

This implementation offers even improved isolation. Different implementations of the concept trade off isolation and MUTE/ACTIVE settling time. In all cases, the input voltages have been muted and are no longer full scale-inputs fed through capacitive coupling to the summing node, resulting in a significant feedthrough reduction and therefore an extension in the useable range of the ADC.

The following table gives sample values for the components of the pre-amplifier circuits of FIGS. 7-9:
R1=100 Ω
R2=3 KΩ
R3=3 KΩ
R4=3.9 KΩ (used in FIG. 7 only)
I1=100 μA
I2=100 μA
I3=100 μA
I4=50 μA
I5=50 μA

Thus, the present invention has been described herein with reference to a particular embodiment for a particular application: Those having ordinary skill in the art and access to the present teachings will recognize additional modifications, applications and embodiments within the scope thereof. For example, while the illustrative embodiments have been described using npn bipolar transistors, other process technologies may be used without departing from the scope of the present teachings.

It is therefore intended by the appended claims to cover any and all such applications, modifications and embodiments within the scope of the present invention.

Accordingly,

1. A comparator comprising:
a first circuit for comparing: first and second input signals and generating a digital output, and
first means for receiving a control signal and in accordance therewith decoupling said input signals from said output.

2. The invention of claim 1 wherein said first means includes one or more switching circuits.

3. The invention of claim 2 wherein each switching circuit is adapted to receive said control signal and in accordance therewith clamp the signal path between said input signals and said output.

4. The invention of claim 1 wherein said comparator further includes a second circuit for receiving said input signals and outputting them to said first circuit.

5. The invention of claim 4 wherein said second circuit includes a pre-amplifier.

6. The invention of claim 5 wherein said first means includes a switching circuit adapted to receive said control signal and in accordance therewith clamp said pre-amplifier.

7. The invention of claim 5 wherein said pre-amplifier includes an amplifier stage adapted to receive said input signals and output amplified signals to said first circuit.

8. The invention of claim 7 wherein said first means includes a switching circuit adapted to turn on said amplifier stage when said control signal is ‘on’.

9. The invention of claim 8 wherein said switching circuit is adapted to turn off said amplifier stage when said control signal is ‘off’.

10. The invention of claim 7 wherein said first means includes a switching circuit adapted to couple the outputs of said amplifier stage to said first circuit when said control signal is ‘on’.

11. The invention of claim 10 wherein said switching circuit is adapted to steer the outputs of said amplifier stage out of the signal path when said control signal is ‘off’.

12. The invention of claim 10 wherein said switching circuit is adapted to couple the outputs of said amplifier stage to AC ground when said control signal is ‘off’.

13. The invention of claim 1 wherein said comparator further includes a latch for holding said digital output.

14. The invention of claim 13 wherein said control signal is adapted to decouple said input signals after said output is captured by said latch.

15. A comparator comprising:
a first circuit for receiving first and second input signals;
a second circuit for comparing said input signals and generating a digital output; and
a switching circuit adapted to receive a control signal and in accordance therewith decouple said input signals from said output.

16. An analog to digital converter comprising:
a first circuit for receiving an analog input signal;
a second circuit for generating a digital output from said input signal;
a third circuit for holding said digital output; and.
first means for receiving a control signal and in accordance therewith decoupling said input signal from said third circuit.

17. The invention of claim 16 wherein said first means includes a switching circuit.

18. The invention of claim 17 wherein said switching circuit is adapted to receive said control signal and in accordance therewith clamp the output of said second circuit.

19. The invention of claim 16 wherein said first circuit includes a first sample and hold circuit.

20. The invention of claim 16 wherein said second circuit includes a comparator bank comprised of a plurality of comparators in parallel adapted to compare the output of said first circuit with a plurality of predetermined values.

21. The invention of claim 20 wherein said second circuit further includes a plurality of pre-amplifiers, each pre-amplifier driving a comparator.

22. The invention of claim 21 wherein said second circuit further includes a quantizer ladder adapted to receive the output of said first circuit and supply a plurality of input signals for said pre-amplifiers.

23. The invention of claim 21 wherein said first means includes a plurality of switching circuits adapted to decouple said pre-amplifiers from said comparators.

24. The invention of claim 20 wherein said third circuit includes a plurality of latches for storing the outputs of said comparators.

25. The invention of claim 24 wherein said first means includes a plurality of switching circuits adapted to decouple said comparators from said latches.

26. The invention of claim 24 wherein said control signal is adapted to decouple said input signal after said comparator outputs are held by said latches.

27. The invention of claim 16 wherein said analog to digital converter further includes a fourth circuit for subtracting an analog version of said digital output from said analog input signal to generate a residue signal.

28. The invention of claim 27 wherein said fourth circuit includes a second sample and hold circuit adapted to sample the output of said first circuit.

29. The invention of claim 28 wherein said fourth circuit further includes a digital to analog converter adapted to convert said digital output to analog.

30. The invention of claim 29 wherein said fourth circuit further includes a summing node adapted to subtract the output of said digital to analog converter from the output of said second sample and hold.

31. The invention of claim 27 wherein said analog to digital converter further includes one or more additional stages for digitizing said residue signal.

32. The invention of claim 31 wherein said additional stages each include a fifth circuit for generating a residue digital output and a sixth circuit for holding said residue digital output.

33. The invention of claim 32 wherein said some of said additional stages further include switching circuits adapted to receive a control signal and in accordance therewith decouple the input to said stage from said sixth circuit.

34. The invention of claim 32 wherein said some of said additional stages further include a reconstruction circuit adapted to subtract said residue digital output from the input to said stage to generate an additional residue signal, which is subsequently input to the next stage.

35. The invention of claim 32 wherein said analog to digital converter further includes an error correction circuit for combining said digital outputs to generate a digital word representing said analog input signal.

36. An analog to digital converter comprising:
a sample and hold circuit adapted to receive an analog input signal and output a sampled voltage;
a quantizer for generating a digital output from said sampled voltage;
a plurality of latches for holding said digital output; and
a switching circuit adapted to receive a control signal and in accordance therewith decouple said sampled voltage from said latches.

37. A subranging analog to digital converter comprising:
a sample and hold circuit adapted to receive an analog input signal and output a sampled voltage;
one or more subranging stages connected in series for digitizing said sampled voltage, each subranging stage including:
a quantizer including a plurality of parallel comparators for generating a digital output from the input to that stage;
a plurality of latches for holding the outputs of said comparators;
a plurality of switching circuits adapted to receive a control signal and in accordance therewith clamp said comparators; and
a reconstruction circuit adapted to subtract an analog version of said digital output from the input to said stage to generate a residue signal, which is subsequently input to the next stage;
a quantizer for generating a digital output from the residue signal of the last subranging stage; and
an error correction circuit for combining said digital outputs to generate a digital word representing said analog input signal.

38. A pre-amplifier comprising:
an amplifier circuit adapted to receive an input signal and output an output signal, and
a switching circuit adapted to receive a control signal and in accordance therewith clamp the output of said amplifier circuit.

39. The invention of claim 38 wherein said amplifier circuit includes a differential pair of transistors Q3 and Q4.

40. The invention of claim 39 wherein the collectors of Q3 and Q4 are each connected to a voltage supply V_{CC} through a resistor.

41. The invention of claim 39 wherein said pre-amplifier further includes an input circuit for supplying a differential input signal to the bases of Q3 and Q4.

42. The invention of claim 41 wherein said input circuit includes a pair of emitter followers Q1 and Q2.

43. The invention of claim 42 wherein the bases of Q1 and Q2 are adapted to receive a differential input signal.

44. The invention of claim 42 wherein the collectors of Q1 and Q2 are connected in common to a voltage supply V_{CC} through a resistor R1.

45. The invention of claim 42 wherein the emitters of Q1 and Q2 are coupled to the bases of Q4 and Q3, respectively.

46. The invention of claim 42 wherein the emitters of Q1 and Q2 are each coupled to a current source I1 and I2, respectively.

47. The invention of claim 39 wherein said pre-amplifier further includes an output circuit adapted to output a differential signal output from Q3 and Q4.

48. The invention of claim 47 wherein said output circuit includes a pair of emitter followers Q9 and Q10.

49. The invention of claim 48 wherein the collectors of Q9 and Q10 are connected to a voltage supply V_{CC}.

50. The invention of claim 48 wherein the bases of Q9 and Q10 are coupled to the collectors of Q4 and Q3, respectively.

51. The invention of claim 48 wherein the emitters of Q9 and Q10 are each coupled to a current source I4 and I5, respectively.

52. The invention of claim 51 wherein one or more diodes are connected in series between the emitter of Q9 and said current source I4.

53. The invention of claim 51 wherein the one or more diodes are connected in series between the emitter of Q10 and said current source I5.

54. The invention of claim 39 wherein said switching circuit is adapted to couple a current source I3 to the common emitters of Q3 and Q4 when said control signal is ‘on’.

55. The invention of claim 54 wherein said switching circuit is adapted to couple said current source I3 to the collectors of Q3 and Q4 when said control signal is ‘off’.

56. The invention of claim 55 wherein said switching circuit includes a differential pair of transistors Q5 and Q6.

57. The invention of claim 56 wherein the emitters of Q5 and Q6 are connected in common to said current source I3.

58. The invention of claim 56 wherein the bases of Q5 and Q6 are connected to complementary control signals V_{ON} and V_{MUTE}, respectively.

59. The invention of claim 56 wherein the collector of Q5 is coupled to the common emitters of Q3 and Q4.

60. The invention of claim 56 wherein the collector of Q6 is coupled to the common emitters of a cascode pair Q7 and Q8.

61. The invention of claim 60 wherein the collector of Q7 is coupled to the collector of Q3.

62. The invention of claim 60 wherein the collector of Q8 is coupled to the collector of Q4.

63. The invention of claim 60 wherein the bases of Q7 and Q8 are connected in common to a reference voltage V_{REF}.

64. The invention of claim 47 wherein said switching circuit is adapted to steer the collector currents of Q3 and Q4 to the output circuit when said control signal is ‘on’.

65. The invention of claim 64 wherein said switching circuit is adapted to steer the collector currents of Q3 and Q4 to AC ground when said control signal is ‘off’.

66. The invention of claim 65 wherein said switching circuit includes a first differential pair Q17 and Q18 having emitters connected in common to the collector of Q3.

67. The invention of claim 66 wherein said switching circuit further includes a second differential pair Q19 and Q20 having emitters connected in common to the collector of Q4.

68. The invention of claim 67 wherein the bases of Q17 and Q20 are connected to a control signal V_{ON}, and the bases of Q18 and Q19 are connected to a control signal V_{MUTE}, which is the complement of V_{ON}.

69. The invention of claim 67 wherein the collectors of Q17 and Q20 are each coupled to the voltage supply V_{CC} through a resistor.

70. The invention of claim 67 wherein the collectors of Q18 and Q19 are coupled directly to the voltage supply V_{CC}.

71. The invention of claim 67 wherein the collectors of Q17 and Q20 are coupled to the output circuit.

72. The invention of claim 64 wherein the emitters of Q3 and Q4 are connected in common to a current source I3.

73. A method for reducing signal feedthrough in an analog to digital converter including the steps of:
sampling and holding an analog input signal;
generating a digital output from the sampled signal; 0.5 latching said digital output;
decoupling said sampled signal from the latched output; and
sampling the next value of the input signal.

74. A method for reducing signal feedthrough in a comparator circuit including the steps of:
receiving first and second input signals;
comparing said input signals and generating a digital output;
latching said digital output; and
decoupling said input signals from said output.
